(19) United States
(12) Patent Application Publication
(10) Pub. No.: US 2026/0316613 A1
(43) Pub. Date: Oct. 15, 2026

(54) SYSTEM AND METHOD OF EXECUTING ACTIVE CAPACITY UPDATES ON MULTIPLE CONNECTED BATTERY SYSTEMS

(71) Applicant: GM Global Technology Operations LLC, Detroit, MI (US)

(72) Inventors: Ryan Christopher Mansfield, Madison Heights, MI (US); Justin Anthony Bunnell, Cary, NC (US); James C. Gibbs, Brighton, MI (US); Jochen Willig, Ypsilanti, MI (US); Manoj Ramesh Chaudhari, Commerce Township, MI (US); Robert Stacey, Swartz Creek, MI (US)

(21) Appl. No.: 19/176,553

(22) Filed: Apr. 11, 2025

(51) Int. Cl. B60L 53/62; H02J 3/32; H02J 7/00

(52) U.S. Cl. CPC B60L 53/62; B60L 58/12; G01R 31/387; H02J 3/322; H02J 7/933

(57) ABSTRACT

An energy management system performs a method of performing an active update for a capacity of a first battery. A first end point of the system connects to the first battery and a second end point connects to a second battery. A controller determines a duration of an idle time for the first battery, determines the first battery is in a charged state, runs a feasibility check of the first battery and the second battery for the active update, discharges the first battery to the second battery, obtains a first measurement of an electrical parameter during discharging, charges the first battery from the second battery, obtains a second measurement of the electrical parameter during the charging, and determines the capacity of the first battery from the first measurement and the second measurement.

### INTRODUCTION

The subject disclosure relates to measuring a capacity of a battery of an electric vehicle and, in particular, to a system and method for performing an active update for capacity of a battery of an electric vehicle while the electric vehicle is idle.

An electric vehicle operates off of an electrical power source such as an electric battery. A capacity of the battery is a measure of a battery's ability to store or deliver electrical energy. Thus, it is useful to be able to determine the capacity at some time during the lifetime of the battery. The capacity is generally tested while the battery is being charged after the vehicle has been driven for an amount that has discharged the battery. This testing method therefore requires coordination with the driving schedule of the vehicle, which limits the times at which the capacity can be tested. Also, the need for the battery to be discharged by driving the vehicle requires a person to dedicate a considerable amount of time just to driving the vehicle to achieve the discharged state. Accordingly, it is desirable to provide a method for performing a capacity update that can be performed without requiring dedicated driving time from an individual.

### SUMMARY

In one exemplary embodiment, a method of performing an active update for a capacity of a first battery is disclosed. The method includes determining a duration of an idle time for the first battery, connecting the first battery to a second battery, wherein the first battery is in a charged state, running a feasibility check of the first battery and the second battery for the active update, discharging the first battery to the second battery, obtaining a first measurement of an electrical parameter during discharging, charging the first battery from the second battery, obtaining a second measurement of the electrical parameter during the charging, and determining the capacity of the first battery from the first measurement and the second measurement.

In addition to one or more of the features described herein, the method further includes connecting the first battery to the second battery via a bidirectional charger.

In addition to one or more of the features described herein, the bidirectional charger is one of a component of an energy management system and a component of a first vehicle.

In addition to one or more of the features described herein, the method further includes setting the first battery to within a high energy region and discharging the first battery from an energy level within the high energy region to within a low energy region by charging to the second battery.

In addition to one or more of the features described herein, the method further includes determining the energy level of the first battery to be within the high energy region by measuring at least one of a slope between open circuit voltage and state of charge and a low hysteresis uncertainty.

In addition to one or more of the features described herein, the method further includes one of discharging the first battery to an electrical grid when the second battery is fully charged as a result of discharging the first battery to the second battery and charging the first battery from the electrical grid when the second battery is fully discharged as a result of charging the first battery from the second battery.

In addition to one or more of the features described herein, wherein the first battery includes a first battery pack and a second battery pack, the method further includes performing the active update at the first battery pack and performing the active update at the second battery pack when the active update is completed at the first battery pack.

In addition to one or more of the features described herein, running the feasibility check further includes comparing a first expected total capacity of the first battery to a total initial energy between the first battery and the second battery and comparing a second expected total capacity of the second battery to the total initial energy.

In addition to one or more of the features described herein, the feasibility check includes energy consumed by parasitic loads.

In addition to one or more of the features described herein, the first battery powers a first vehicle and the second battery is at least one of a stationary storage system, a component of a second vehicle, an electrical grid. and a peer.

In another exemplary embodiment, an energy management system for performing an active update of a capacity of a first battery is disclosed. The energy management system includes a first end point for connected to the first battery, a second end point for connecting to a second battery, and a controller. The controller is configured to determine a duration of an idle time for the first battery, determine the first battery is in a charged state, run a feasibility check of the first battery and the second battery for the active update, discharge the first battery to the second battery, obtain a first measurement of an electrical parameter during discharging, charge the first battery from the second battery, obtain a second measurement of the electrical parameter during the charging, and determine the capacity of the first battery from the first measurement and the second measurement.

In addition to one or more of the features described herein, the energy management system further includes a bidirectional charger for connecting the first battery to the second battery.

In addition to one or more of the features described herein, wherein the bidirectional charger is one of a component of the energy management system and a component of a first vehicle.

In addition to one or more of the features described herein, the controller is further configured to set the first battery to within a high energy region and discharge the first battery from an energy level within the high energy region to within a low energy region by charging to the second battery.

In addition to one or more of the features described herein, the controller is further configured to determine the energy level of the first battery to be within the high energy region by measuring at least one of a slope between open circuit voltage and state of charge and a low hysteresis uncertainty.

In addition to one or more of the features described herein, the controller is further configured to perform one of discharging the first battery to an electrical grid when the second battery is fully charged as a result of discharging the first battery to the second battery and charging the first battery from the electrical grid when the second battery is fully discharged as a result of charging the first battery from the second battery.

In addition to one or more of the features described herein, wherein the first battery includes a first battery pack and a second battery pack and the controller is further configured to perform the active update at the first battery pack and perform the active update at the second battery pack when the active update is completed at the first battery pack.

In addition to one or more of the features described herein, the controller is further configured to run the feasibility check by comparing a first expected total capacity of the first battery to a total initial energy between the first battery and the second battery and comparing a second expected total capacity of the second battery to the total initial energy.

In addition to one or more of the features described herein, wherein the feasibility check includes energy consumed by parasitic loads.

In addition to one or more of the features described herein, wherein the first battery powers a first vehicle and the second battery is at least one of a stationary storage system, a component of a second vehicle, an electrical grid, a peer.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings in which:

FIG. 1 shows a vehicle in accordance with an exemplary embodiment;

FIG. 2 is a diagram of an energy management system that is suitable for performing an active update on the vehicle of FIG. 1;

FIG. 3 is a diagram of a section of the energy management system of FIG. 2;

FIG. 4 is a diagram showing an operation of the energy management system in a first charging configuration;

FIG. 5 is a diagram illustrating another configuration including a direct connection between vehicles;

FIG. 6 is a diagram showing an operation of the energy management system in another configuration;

FIG. 7 is a diagram showing an operation of the energy management system in another configuration;

FIG. 8 is a diagram illustrating charging of the first vehicle using yet another charging configuration;

FIG. 9 shows an energy diagram for two batteries used in an active update of a capacity;

FIG. 10 is a diagram illustrating energy requirements of the first battery;

FIG. 11 shows battery requirements for a scenario in which the second battery is charged by the second battery;

FIG. 12 is a diagram illustrating a feasibility check for an active capacity update performed on the second battery;

FIG. 13 is a diagram illustrating battery requirements when the second battery is discharged to the first battery during a second active update of capacity;

FIG. 14 is a flowchart of a method for performing an active update, in an illustrative embodiment;

FIG. 15 is a flowchart of a method for performing an active update for a plurality of battery packs within a vehicle, as shown in FIG. 7; and

FIG. 16 is a flowchart of a method for determining a method for active update for a parallel pack system.

### DETAILED DESCRIPTION

The following description is merely exemplary in nature and is not intended to limit the present disclosure, its application or uses. It should be understood that throughout the drawings, corresponding reference numerals indicate like or corresponding parts and features.

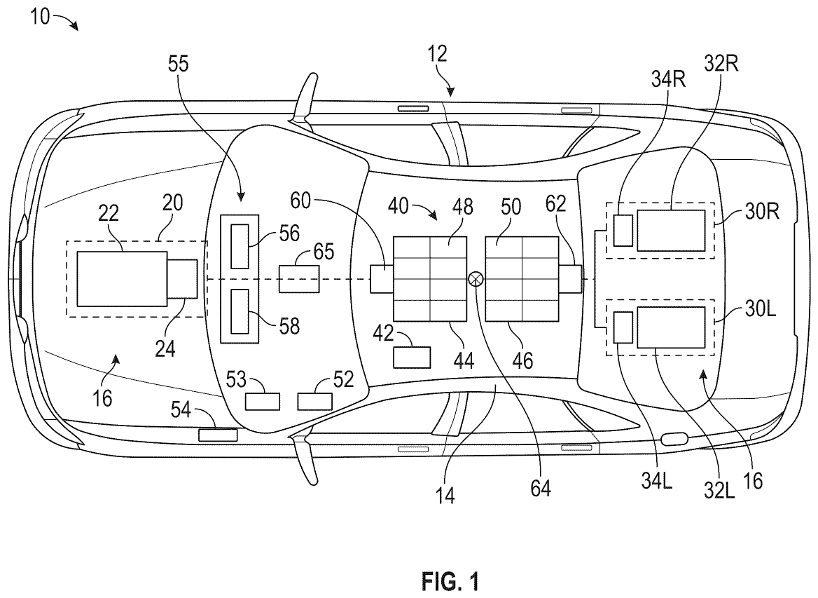

In accordance with an exemplary embodiment, FIG. 1 shows an embodiment of a vehicle 10, which includes a vehicle body 12 defining, at least in part, an occupant compartment 14. The vehicle body 12 also supports various vehicle subsystems including a propulsion system 16, and other subsystems to support functions of the propulsion system 16 and other vehicle components, such as a braking subsystem, a suspension system, a steering subsystem, and others.

The vehicle 10 may be an electrically powered vehicle (EV), a hybrid vehicle or any other vehicle. In an embodiment, the vehicle 10 is an electric vehicle that includes multiple motors and/or drive systems. Any number of drive units may be included, such as one or more drive units for applying torque to front wheels (not shown) and/or to rear wheels (not shown). The drive units are controllable to operate the vehicle 10 in various operating modes, such as a normal mode, a high performance mode (in which additional torque is applied), all-wheel drive (“AWD”), front-wheel drive (“FWD”), rear-wheel drive (“RWD”) and others.

For example, the propulsion system 16 is a multi-drive system that includes a front drive unit 20 for driving front wheels, and rear drive units for driving rear wheels. The front drive unit 20 includes a front electric motor 22 and a front inverter 24 (e.g., front power inverter module or FPIM), as well as other components such as a cooling system. A left rear drive unit 30L includes a left rear electric motor 32L and a left rear inverter 34L. A right rear drive unit 30R includes a right rear electric motor 32R and a right rear inverter 34R. The front inverter 24, left rear inverter 34L and right rear inverter 34R (e.g., power inverter units or PIMs) each convert direct current (DC) power from a high voltage (HV) battery system 40 to poly-phase (e.g., two-phase, three-phase, six-phase, etc.) alternating current (AC) power to drive the front electric motor 22 and the left rear electric motor 32L and the right rear electric motor 32R.

As shown in FIG. 1, the drive systems feature separate electric motors. However, embodiments are not so limited. For example, instead of separate motors, multiple drives can be provided by a single machine that has multiple sets of windings that are physically independent.

As also shown in FIG. 1, the drive systems are configured such that the front electric motor 22 drives the front wheels (not shown), and the left rear electric motor 32L and right rear electric motor 32R drive the rear wheels (not shown).

However, embodiments are not so limited, as there may be any number of drive systems and/or motors at various locations (e.g., a motor driving each wheel, twin motors per axle, etc.). In addition, embodiments are not limited to a dual drive system, as embodiments can be used with a vehicle having any number of motors and/or power inverters.

In the propulsion system 16, the front drive unit 20, left rear drive unit 30L and right rear drive unit 30R are electrically connected to the battery system 40. The battery system 40 may also be electrically connected to other electrical components (also referred to as “electrical loads”), such as vehicle electronics (e.g., via an auxiliary power module or APM 42), heaters, cooling systems and others. The battery system 40 may be configured as a rechargeable energy storage system (RESS).

In an embodiment, the battery system 40 includes a plurality of separate battery assemblies, in which each battery assembly can be independently charged and can be used to independently supply power to a drive system or systems. For example, the battery system 40 includes a first battery assembly such as a first battery pack 44 connected to the front inverter 24 and a second battery pack 46. The first battery pack 44 includes a first plurality of battery modules 48, and the second battery pack 46 includes a second plurality of battery modules 50. Each of the first plurality of battery modules 48 and the second plurality of battery modules 50 includes a number of individual cells (not shown).

Each of the front electric motor 22 and the left rear electric motor 32L and right rear electric motor 32R is a three-phase motor having three phase motor windings. However, embodiments described herein are not so limited. For example, the motors may be any poly-phase machines supplied by poly-phase inverters, and the drive units can be realized using a single machine having independent sets of windings.

The battery system 40 and/or the propulsion system 16 includes a switching system having various switching devices for controlling operation of the first battery pack 44 and second battery pack 46, and selectively connecting the first battery pack 44 and second battery pack 46 to the front drive unit 20, left rear drive unit 30L and right rear drive unit 30R. The switching devices may also be operated to selectively connect the first battery pack 44 and the second battery pack 46 to a charging system. The charging system can be used to charge the first battery pack 44 and the second battery pack 46, and/or to supply power from the first battery pack 44 and/or the second battery pack 46 to charge another energy storage system (e.g., vehicle-to-vehicle (V2V) and/or vehicle-to-everything (V2X) charging). The charging system includes one or more charging modules. For example, a first onboard charging module (OBCM) 52 is electrically connected to a charge port 54 for charging to and from an AC system or device, such as a utility AC power supply. A second OBCM 53 may be included for DC charging (e.g., DC fast charging or DCFC).

In an embodiment, the switching system includes a first switching device 60 that selectively connects to the first battery pack 44 to the front inverter 24, left rear inverter 34L and right rear inverter 34R, and a second switching device 62 that selectively connects the second battery pack 46 to the front inverter 24, left rear inverter 34L and right rear inverter 34R. The switching system also includes a third switching device 64 (also referred to as a “battery switching device”) for selectively connecting the first battery pack 44 to the second battery pack 46 in series. Any of various controllers can be used to control functions of the battery system 40, the switching system and the drive units. A controller includes any suitable processing device or unit and may use an existing controller such as a drive system controller, a RESS controller, and/or controllers in the drive system. For example, a controller 65 may be included for controlling switching and drive control operations as discussed herein.

The vehicle 10 also includes a computer system 55 that includes one or more processing devices 56 and a user interface 58. The computer system 55 may communicate with the charging system controller, for example, to provide commands thereto in response to a user input. The various processing devices, modules and units may communicate with one another via a communication device or system, such as a controller area network (CAN) or transmission control protocol (TCP) bus.

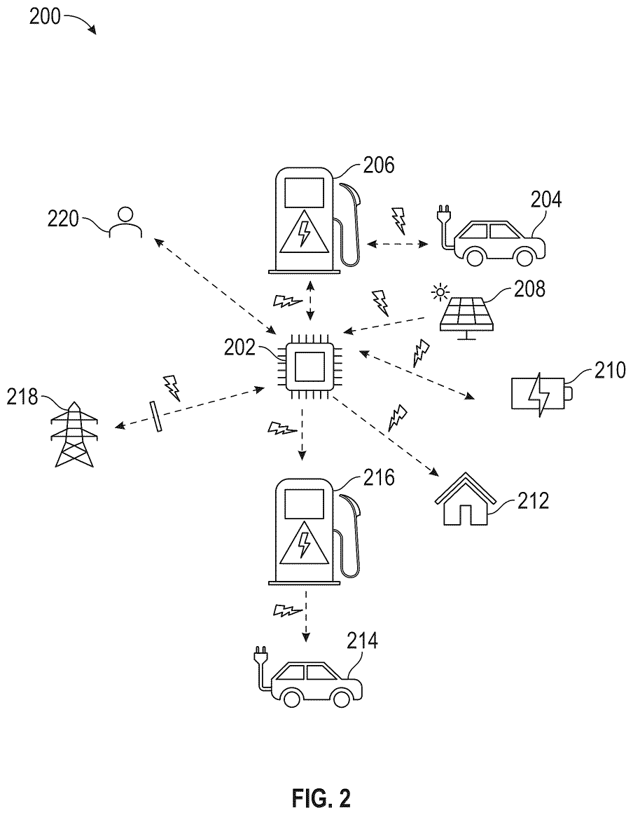

FIG. 2 is a diagram of an energy management system 200 that is suitable for performing an active update on the vehicle 10 of FIG. 1. The energy management system 200 includes a controller 202 and allows for electric connections between various endpoints. The controller 202 may include processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality. The controller 202 may also include a non-transitory computer-readable medium that stores instructions which are processed by one or more processors of the controller to implement processes detailed herein.

The controller 202 can facilitate transfer of energy as well as data between these endpoints. For illustrative purposes, the endpoints include a first vehicle 204 (which can be vehicle 10) which connects to the controller 202 through a bidirectional charger 206, a solar photovoltaic device 208, a stationary storage device 210 (such as a home back-up system), various building loads 212, a second vehicle 214 (shown here connected to the controller 202 via a unidirectional charger 216), and an electric grid 218. An EV owner 220 can communicate with the energy management system 200. For example the EV owner 220 can input mobility needs (e.g., at what time of the day the state of charge of the electric vehicle needs to be at a selected state of charge).

The controller 202 manages energy transfer plans and schedules active updates. Scheduling considers the mobility needs of a vehicle, such as an expected departure time for the vehicle and an energy need of the vehicle, as well as various grid information, such as grid status, energy prices, weather conditions, etc., solar photovoltaic production, building loads, the energy storage capacity of stationary storage device 210, etc.

The active update is a test for determining a current capacity of the battery. The active update disclosed herein employs bidirectional charging between a first battery and a reserve battery such as a second battery. The active update is performed by discharging the first battery from its current charge state by transferring charge to the second battery. Once the first battery is discharged, the first battery is recharged. The discharge is through the energy management system 200, rather than by driving the vehicle until it is discharged. The level to which the first battery is able to be recharged is recorded as the capacity of the first battery. The capacity is given as shown in Eq. (1):

Capacity=(Net ΔAamphours)/ΔSOC Eq. (1)

where SOC is the state of charge. The first battery can be recharged by transferring charge from the second battery. Given enough time, an active update can be performed on the second battery using the first battery as the reserve battery.

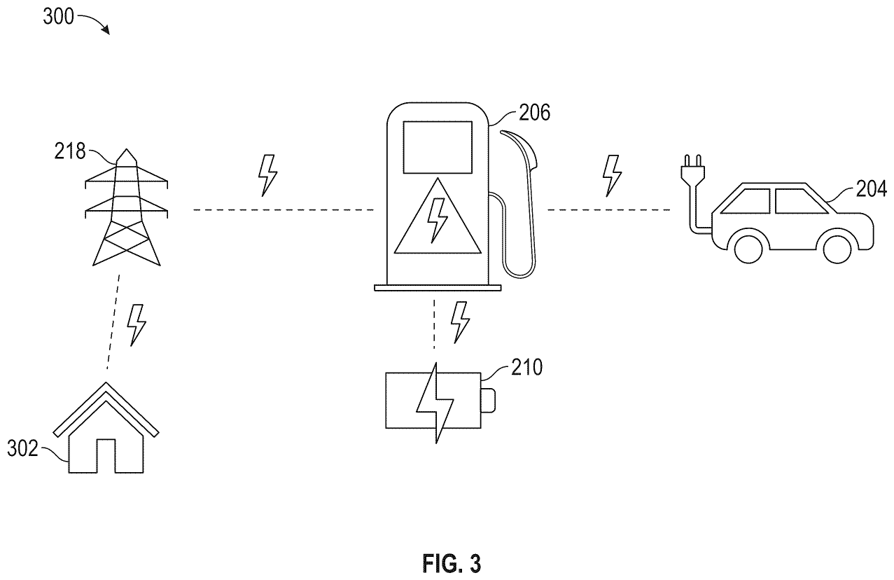

FIG. 3 is a diagram of a section 300 of the energy management system 200 of FIG. 2. The section 300 shows a configuration including selected endpoints of the energy management system 200. The configuration includes the first vehicle 204, bidirectional charger 206, the stationary storage device 210, the electric grid 218, and a peer 302. The peer 302 can be suitable platform, such as a vehicle dealership, a business, another vehicle, etc. The first vehicle 204 connects to these other devices via the bidirectional charger 206. The active update can be performed between the first vehicle 204 and any of the stationary storage device 210, the electric grid 218 and the peer 302. In the configuration of FIG. 3, the first battery system can be the battery of the first vehicle 204 and the second battery system can be any of the stationary storage device 210, the electric grid 218, and the peer 302. In other embodiments, the secondary battery system can be the stationary storage device 210, the electric grid 218, and the peer 302 working together or in combination.

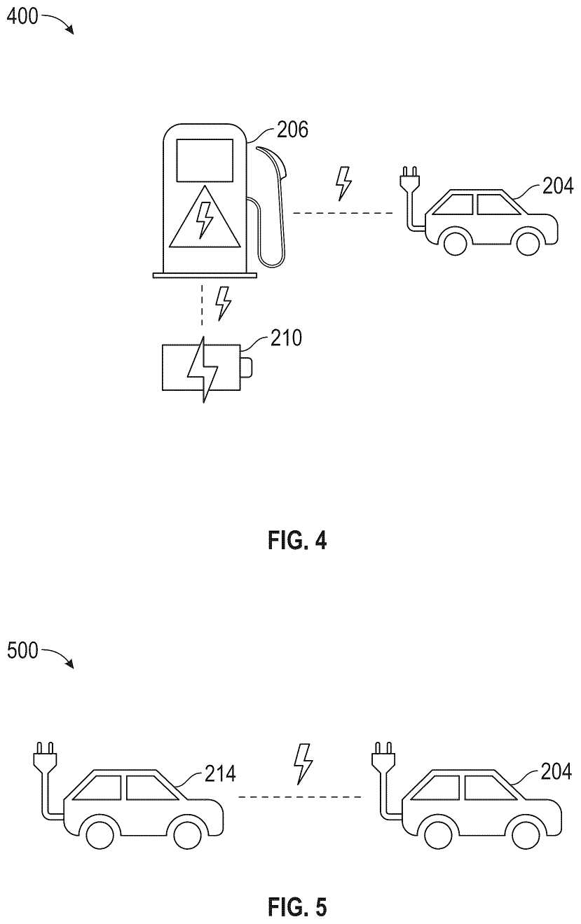

FIG. 4 is a diagram 400 showing an operation of the energy management system 200 in a first charging configuration. The first charging configuration is between the first vehicle 204 and a stationary storage device 210.

The first vehicle 204 is connected to the stationary storage device 210 via the bidirectional charger 206. As the first vehicle 204 is parked at a residence or home, the energy management system 200 can charge and discharge the battery of the vehicle while the vehicle is idle or off, such as overnight or when the owner of the first vehicle 204 is away from the residence or on vacation. In other words, the vehicle can be discharged and charged while the vehicle is not directly being utilized for other mobility or transportation purposes.

As the charging is bi-directional, the first configuration can be used to simultaneously determine a capacity for both the battery of the first vehicle 204 and the stationary storage device 210. A bulk of the energy is exchanged between the first vehicle 204 and the stationary storage device 210. Electrical loss can be restricted to those losses occurring at the bidirectional charger and any 12-Volt losses of the first vehicle 204.

FIG. 5 is a diagram 500 illustrating another configuration including a direct connection between vehicles. In this configuration, the first vehicle 204 is directly connected to another vehicle (which can be the second vehicle 214). A controller of the first vehicle can be used to control a bi-directional connection between vehicles. The configuration allows for simultaneous capacity updates on the batteries of both the first vehicle 204 and the second vehicle 214. This configuration is useful for performing an active update for a fleet of vehicles, such as vehicles of a dealership.

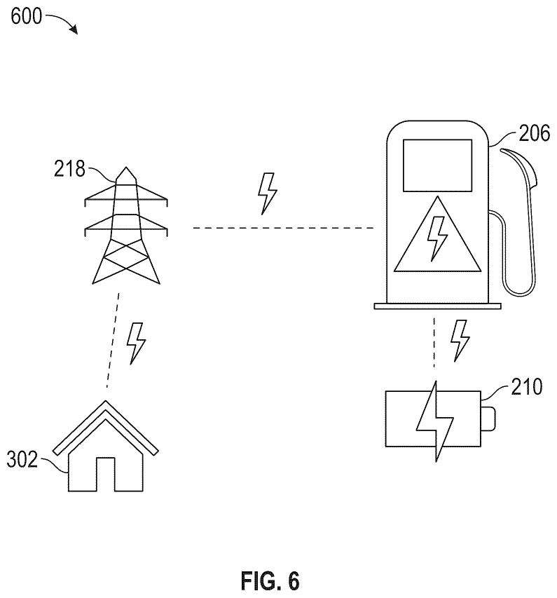

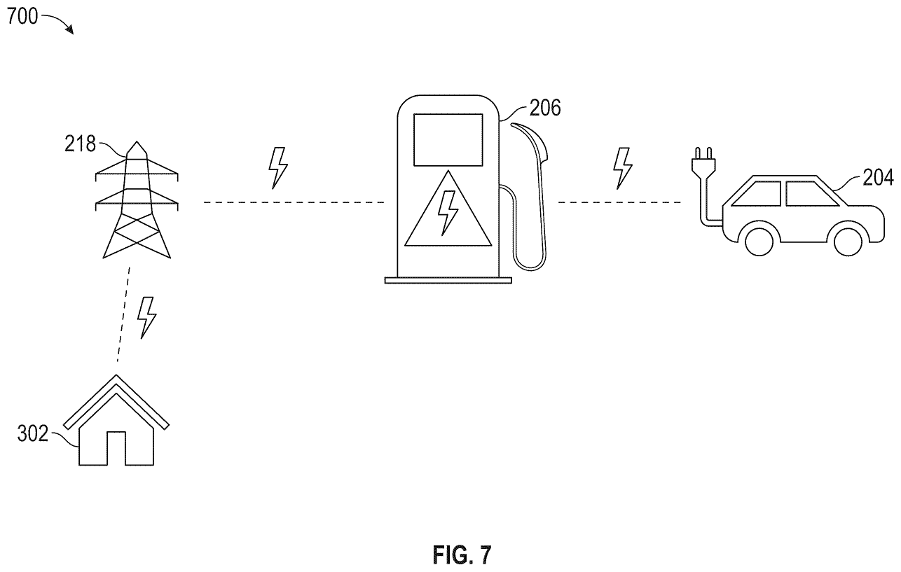

FIG. 6 is a diagram 600 showing an operation of the energy management system 200 in another configuration. The configuration includes an electrical connection between the stationary storage device 210 and the electric grid 218/peer 302. The stationary storage device 210 can exchange energy directly with the electric grid 218 or with the peer 302. The active update can be scheduled for a time at which the electric rates and/or electric demand are low.

FIG. 7 is a diagram 700 showing an operation of the energy management system 200 in another configuration. The configuration includes an electrical connection between the first vehicle 204 and the electric grid 218/peer 302. The first vehicle 204 can exchange energy directly with the electric grid 218 (V2G) or with the peer 302. Similar to FIG. 6, the active update can be scheduled for a time at which the electric rates and/or electric demand are low.

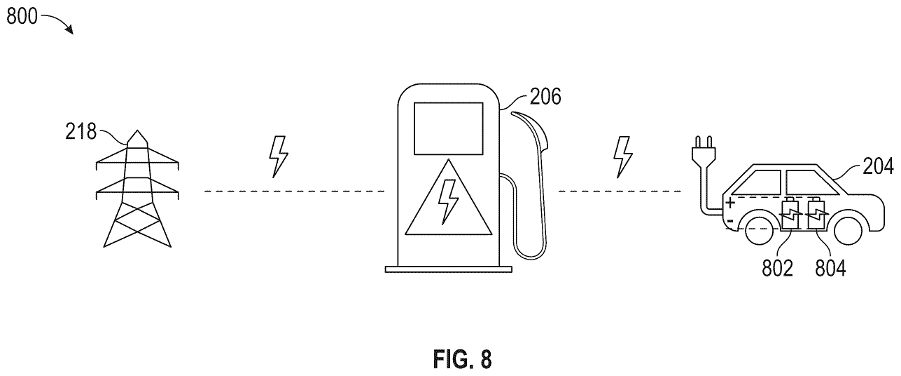

FIG. 8 is a diagram 800 illustrating charging of the first vehicle 204 using yet another charging configuration. The configuration shows the first vehicle 204 connected to the electric grid 218 via the bidirectional charger 206. The first vehicle 204 is shown with a first battery pack 802 and a second battery pack 804. An active update can be performed on the first battery pack 802 while the second battery pack 804 is offline. After the active update is completed, the first battery pack 802 rests as another active update is performed on the second battery pack 804. Thus, each battery pack can be tested independently and one at a time. A controller prioritizes the active update on one battery pack without degrading the overall charging performance of the vehicle. This configuration can also be used in non-automotive applications (i.e., in stationary energy storage).

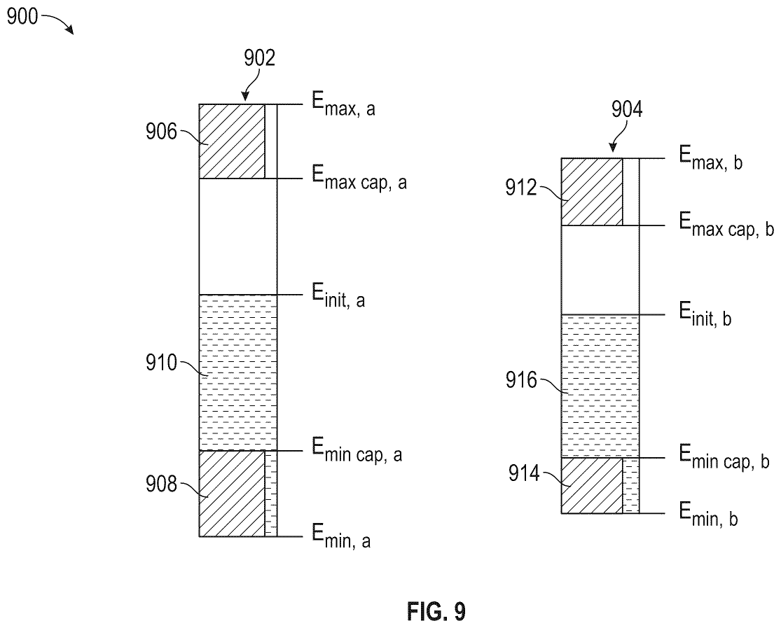

FIGS. 9-13 are diagrams illustrating a feasibility check for a first battery and a second battery that is performed before performing an active update on either battery.

FIG. 9 shows an energy diagram 900 for two batteries used in an active update of a capacity. For illustrative purposes, the two batteries include a first battery 902 associated with a first vehicle (Vehicle A) and a second battery 904 associated with a second vehicle (Vehicle B). The energy diagram 900 includes two rectangles, each rectangle representing an energy capacity of a battery. The energy capacity of each battery is represented by a height of their respective rectangles. As indicated by differences in the heights of the respective rectangles, the first total capacity (or the first expected total capacity) of the first battery 902 is greater than the second total capacity (or the second expected total capacity) of the second battery 904.

For the first battery 902, the maximum energy is indicated by E_{max,a} and the minimum energy is indicated by E_{min,a}. The first battery 902 includes a high energy region 906 and a low energy region 908. The high energy region 906 is bounded by the maximum energy (E_{max,a}) and a high energy lower bound (E_{max cap,a}). The low energy region 908 is bounded by a minimum energy (E_{min,a}) and a low energy upper bound (E_{min cap,a}). The high energy region 906 and the low energy region 908 can be determined using various parameters, such as chemistry (OCV/SOC slope (slope between open circuit voltage and state of charge), hysteresis effects, etc.) sufficient ΔAmp-hrs between the upper and lower capacity point based on V/I sensor accuracy, etc. A current energy state of the first battery 902 is indicated by the height (E_{init,a}) of area 910.

Similarly, for the second battery 904, the maximum energy is indicated by Emax, b and the minimum energy is indicated by E_{min,b}. The second battery 940 includes a high energy region 912 and a low energy region 914. The high energy region 912 is bounded by the maximum energy (E_{max,b}) and a high energy lower bound (E_{max cap,b}). The low energy region 914 is bounded by a minimum energy (E_{min,b}) and a low energy upper bound (E_{min cap,b}). A current energy state of the second battery 904 is indicated by the height (E_{init,b}) of area 916.

The total initial energy of the system including both the first battery 902 and the second battery 904 is given in Eq. (2)

Total Init Energy=E_{init,a}−E_{min,a}+E_{init,b}−E_{min,b} Eq. (2)

Battery systems and/or vehicles can have parasitic loads from powering 12V loads to power controllers, and additional losses from moving electrical energy from one battery to another (e.g., ohmic losses, switching losses, etc.). The total of parasitic loads is given in Eq. (3):

ΣParasitic Loads=Parasitic Loadsₐ+Parasitic Loads_{b} Eq. (3)

For the first battery 902 to be suitable for an active update, the first total capacity of the first battery needs to be large enough to store the Total Init Energy. For the active update, the energy level is raised to the high energy region 906. The first battery 902 is then discharged to lower the energy to the low energy region 908. An open circuit voltage (OCV) of the first battery can be measured or modeled for the first battery 902 at the low energy region 908. The measurement or a regressed open circuit voltage from a battery model (e.g., Kalman filter battery model) can be taken with the battery within the high energy region 906 and low energy region 908. A corresponding state of charge can be determined for each of these regions. The net number of amp-hours charged or discharged through the first battery 902 between the SOC determined while in the high energy region 906 and the low energy region 908 is used to calculate capacity (as shown in Eq. (1)) for the first battery. The first battery is then charged, starting from the low energy region 908.

The second battery 904 is used to accommodate the active capacity update on the first battery 902.

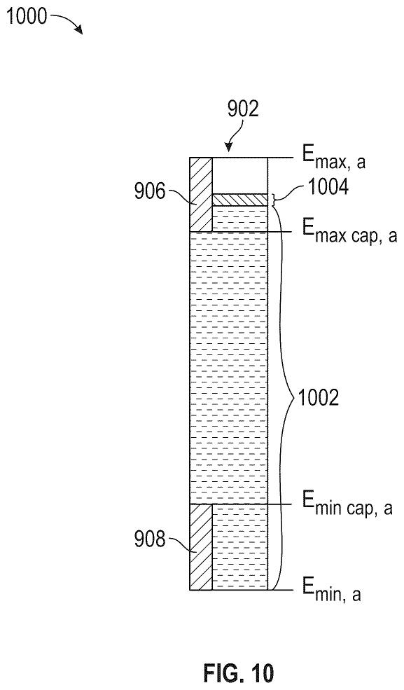

FIG. 10 is a diagram 1000 illustrating energy requirements of the first battery. The total initial energy of the system is shown by energy region 1002. The parasitic loads are shown by parasitic region 1004. In order for an active update of capacity to be successfully performed, the first battery 902 should observe Eq. (4):

E_{max Cap,a}−E_{min,a}<Total Init Energy Eq. (4)

If one includes parasitic loads in the calculation, Eq. (4) can be modified as shown in Eq. (5):

E_{max cap,a}−E_{min,a}<Total Init Energy+ΣParasitic Loads*Expected Update Time Eq. (5)

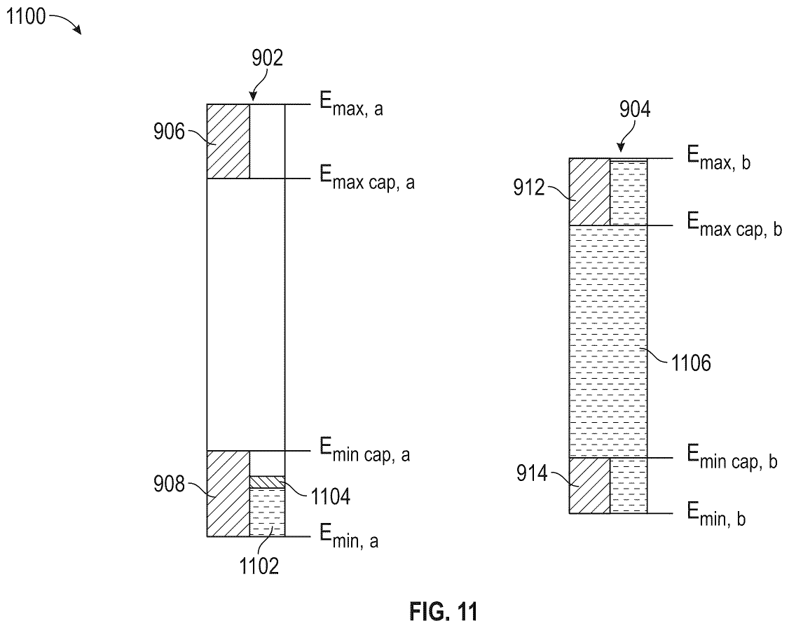

FIG. 11 shows battery requirements for a scenario in which the second battery 904 is charged by the second battery 904. The remaining energy in the first battery 902 is indicated by region 1102 and the parasitic loads are shown by region 1104. In this state, the total initial energy is distributed between region 1102 and region 1106. The second battery 904 needs to have a capacity such that, when fully charged by the first battery 902, the energy remaining in the first battery lies within the low energy region 908. In order for this discharge step to be successful, the batteries should satisfy Eq. (6):

E_{max,b}−E_{min,b}+E_{min cap,a}−E_{min,a}>Total Init Energy Eq. (6)

If parasitic loads are considered, Eq. (6) can be restated as shown in Eq. (7):

E_{max,b}−E_{min,b}+E_{min cap,a}−E_{min,a}>Total Init Energy+ΣParasitic Loads*Expected Cap Update Time Eq. (7)

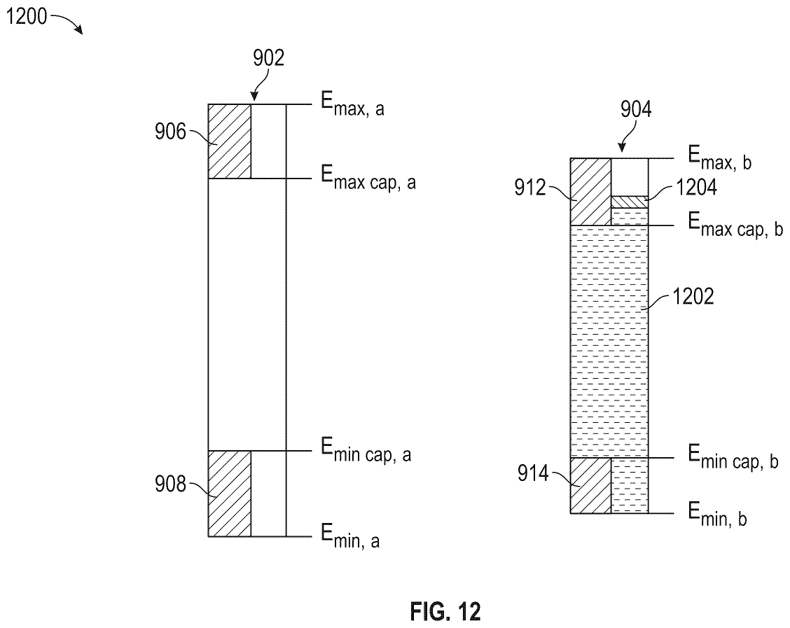

FIG. 12 is a diagram 1200 illustrating a feasibility check for an active capacity update performed on the second battery 904. A second total capacity of the second battery 904 needs to be large enough to store the Total Initial Energy (i.e., to have the energy of the second battery be able to achieve the high energy region 912), as stated in Eq. (8):

E_{max Cap,b}−E_{min,b}<Total Init Energy Eq. (8)

If parasitic loads are considered, Eq. (8) can be rewritten as Eq. (9):

E_{max cap,b}−E_{min,b}<Total Init Energy+ΣParasitic Loads*Expected Cap Update Time Eq. (9)

Total energy 1202 in the second battery 904 and parasitic loads 1204 are shown, for illustrative purposes.

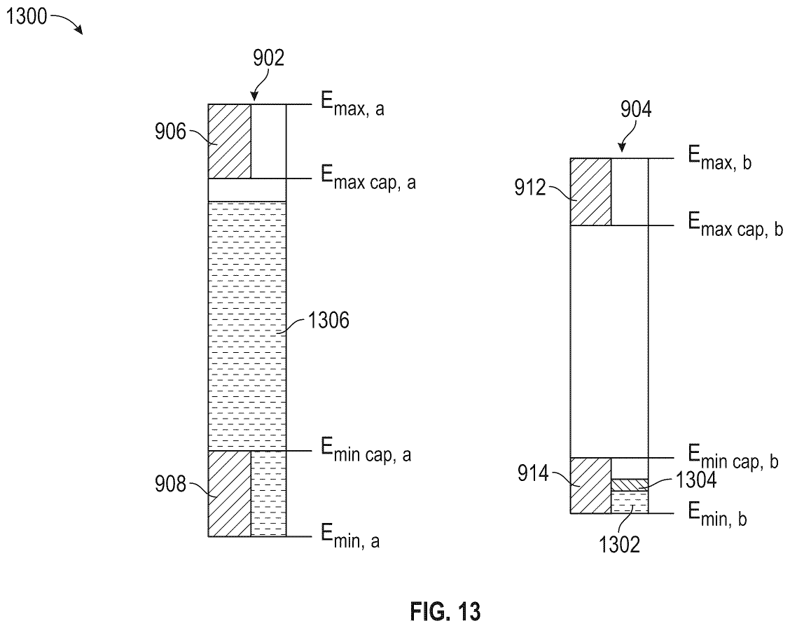

FIG. 13 is a diagram 1300 illustrating battery requirements when the second battery 904 is discharged to the first battery 902 during a second active update of capacity. The second battery 904 is discharged until the remaining energy lies within the low energy region 914. The remaining energy in the second battery 904 is indicated by region 1302 and the parasitic loads are shown by region 1304. The first battery is not fully charged, as shown by region 1306. The total initial energy is thus distributed between region 1302 and region 1306. In order for the discharge step to be successful, the batteries should satisfy Eq. (10):

E_{max,a}−E_{min,a}+E_{min cap,b}−E_{min,b}>Total Init Energy Eq. (10)

If parasitic loads are considered, Eq. (10) can be rewritten as Eq. (11):

E_{max,a}−E_{min,a}+E_{min cap,b}−E_{min,b}>Total Init Energy+ΣParasitic Loads*Expected Cap Update Time Eq. (11)

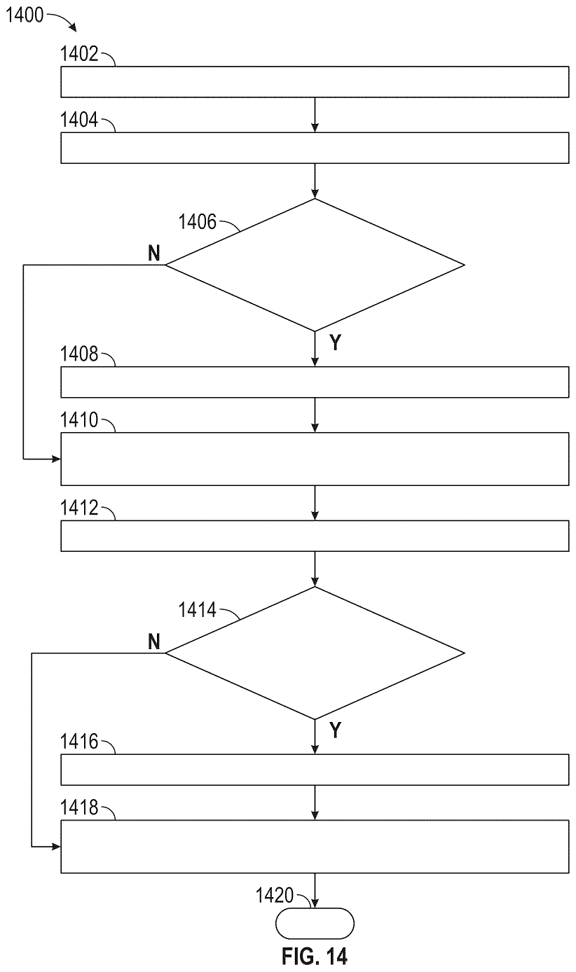

FIG. 14 is a flowchart 1400 of a method for performing an active update, in an illustrative embodiment. The method can be performed between any two battery systems or energy sources. For illustrative purposes only, the method is discussed with a vehicle battery as the first battery system and a stationary storage device as the second battery system. In some embodiments, the capacity of the stationary storage device is less than the capacity of the battery. The connections between battery systems can be direct (i.e., a bidirectional charge), or indirect (e.g., peer to peer power transfer over a command electric grid).

The method starts at box 1402 when the vehicle is plugged into the grid (i.e., the bidirectional charger) and left idle for an amount of time suitable for the active capacity update to be performed. In general, both the vehicle and the storage device are checked to see that both are available for the active update and are not expected to be used before the active update is completed. Scheduling information, such as expected departure time, and charge requirements or other battery specifications can be provided from the vehicle to the controller 202. The information can also include customer preferences, utility requests, energy levels in both the vehicle battery and the storage device, potential energy generation from distributed energy resources, and costs such as efficiency losses.

Additional criteria include the time/distance/energy throughput since the latest update. As this metric increases, the controller 202 can determine a greater need of the update and can prompt the customer to make time for the active update, if necessary. The customer can also provide a target charge level for the vehicle after then update or can schedule a time by which the update is to be completed.

In box 1404, the discharging of the vehicle battery to the stationary device is commenced. In various embodiments, two or more stationary devices can be used, either in series or in parallel. In box 1406, the state of charge (SOC) of the stationary device is monitored during discharge of the vehicle battery. If the SOC of the stationary device reaches an upper SOC limit for the stationary device, the method proceeds to box 1408. In box 1408, the vehicle battery is discharged to an electrical grid. The method then proceeds to box 1410. Alternatively, the method can proceed to box 1410 from box 1406 (i.e., battery fully discharged to the stationary device) if the vehicle is discharged without the stationary device reaching the upper SOC limit. The charge transfer ends when the SOC of the vehicle battery has dropped below a lower SOC limit of the vehicle and the SOC of the storage device has risen above an upper SOC limit of the storage device. The upper bounds and lower bounds can be pre-selected. In box 1410, the discharge of the vehicle battery is completed. The method then allows the vehicle battery to rest as a parameter of the vehicle battery is measured or obtained. The SOC can be determined from a rested open circuit voltage lookup (1 hour rest with no current to allow for voltage to settle), or a regressed open circuit voltage can be obtained from a battery model without the need for a rest.

In box 1412, charging of the vehicle battery is commenced by depleting the stationary device. In box 1414, the SOC of the stationary device is monitored during charging of the vehicle battery. If the SOC of the stationary device reaches a lower SOC limit for the stationary device, the method proceeds to box 1416. In box 1416, the vehicle battery is charged from the electrical grid. The method then proceeds to box 1418. Alternatively, the method can proceed to box 1418 from box 1414 (i.e., battery fully charged from the stationary device) when the vehicle is charged without the stationary device reaching the lower SOC limit.

In box 1418, the SOC of the vehicle battery reaches the upper SOC limit of the vehicle battery and the charging is completed. The method then allows the vehicle battery to rest as a parameter is measured or obtained from the vehicle battery. The parameter can be the same parameter measured in box 1410 (i.e., SOC from a rested open circuit voltage lookup or a regressed open circuit voltage). The capacity can be determined from the change in amp-hours between the two parameter measurements. The method ends at box 1420.

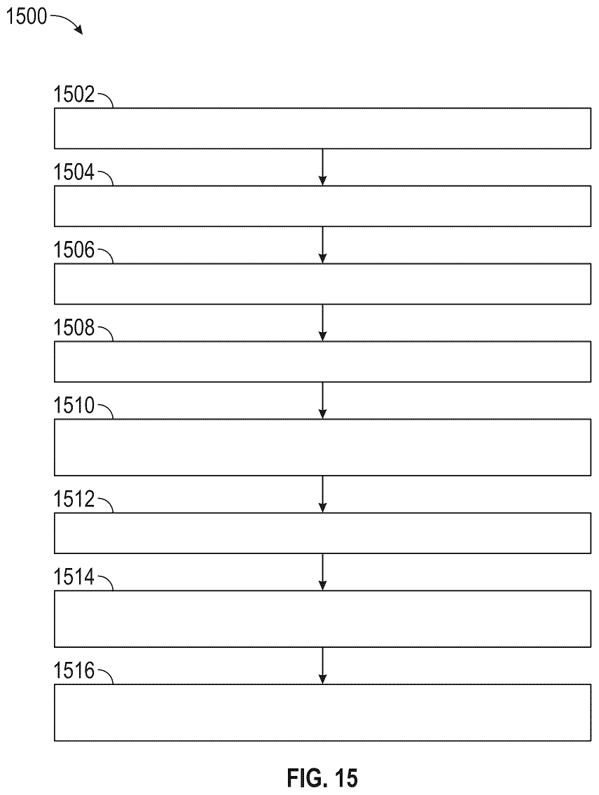

FIG. 15 is a flowchart 1500 of a method for performing an active update for a plurality of battery packs within a vehicle, as shown in FIG. 7. In box 1502, the vehicle is plugged into the bidirectional charger 206 or other suitable EVSE (electrical vehicle supply equipment).

In box 1504, it is determined whether conditions are acceptable for charging a single pack. The conditions can be that the EVSE power is less than a single pack charging power capability or that the that the idle time of the vehicle (time until departure) indicated by the customer allows for the charging of a single pack at a time.

In box 1506, a battery pack is selected from the plurality of battery packs. The battery pack can be selected based on various criteria, including, but not limited to, starting with the oldest battery, starting with the lowest capacity battery, starting with the battery having gone the longest time since the last update, starting with the battery having gone the longest distance since the last update, a service event, etc.

In box 1508, the selected battery pack is brought to an acceptable initial voltage for the active update. As the selected battery pack is brought to the acceptable start voltage, various parameters can be measured to indicate the whether the battery pack is at the acceptable start voltage. Such parameters include an OCV/SOC slope, low hysteresis uncertainty, low enough starting point (enough margin from acceptable voltages later in a charge cycle).

In box 1510, a resting start voltage or a regressed start voltage of the selected battery pack is measured and a start SOC corresponding to the measured start voltage is determined. The start SOC can be determined using, for example, a lookup table. In box 1512, the selected battery pack is brought to an acceptable end voltage. Various parameters can be measured to indicate the whether the battery pack is at the acceptable end voltage. Such parameters include an OCV/SOC slope, low hysteresis uncertainty, low enough starting point (enough margin from acceptable voltages later in a charge cycle).

In box 1514, a resting end voltage or a regressed end voltage of the selected battery pack is measured and an end SOC corresponding to the measured end voltage is determined. The end SOC can be determined using, for example, a lookup table. In box 1516, the battery packs are brought into balance by charging the battery pack having the lowest SOC. This battery pack can be the selected battery pack or a non-selected battery pack.

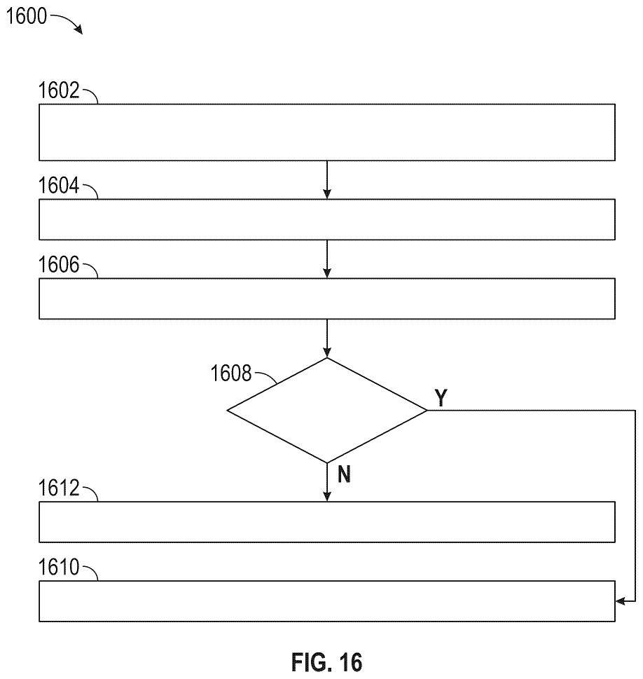

FIG. 16 is a flowchart 1600 of a method for determining a method for active update for a parallel pack system. In box 1602, a vehicle equipped with a parallel pack is plugged into the energy management system. In box 1604, a signal is sent to perform the active update. In box 1606, the SOC of each parallel pack is compared to a threshold values (i.e., 30% SOC). In box 1608, a decision is made based on the comparison. If both parallel packs are acceptable (i.e. SOC less than threshold), the method proceeds to box 1610. In box 1610, the active update is performed as described in FIG. 15. Returning to box 1608, if at least one of the parallel packs are not acceptable, the method proceeds to box 1612. In box 1612, the active update is performed on the packs in parallel.

The terms “a” and “an” do not denote a limitation of quantity, but rather denote the presence of at least one of the referenced item. The term “or” means “and/or” unless clearly indicated otherwise by context. Reference throughout the specification to “an aspect”, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects.

When an element such as a layer, film, region, or substrate is referred to as being “on” another element, it can be directly on the other element or intervening elements may also be present. In contrast, when an element is referred to as being “directly on” another element, there are no intervening elements present.

Unless specified to the contrary herein, all test standards are the most recent standard in effect as of the filing date of this application, or, if priority is claimed, the filing date of the earliest priority application in which the test standard appears.

Unless defined otherwise, technical and scientific terms used herein have the same meaning as is commonly understood by one of skill in the art to which this disclosure belongs.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

1. A method of performing an active update for a capacity of a first battery, comprising:
determining a duration of an idle time for the first battery;
connecting the first battery to a second battery via a bidirectional charger, wherein the first battery is in a charged state;
running a feasibility check of the first battery and the second battery for the active update;
discharging the first battery to the second battery;
obtaining a first measurement of an electrical parameter during discharging;
charging the first battery from the second battery;
obtaining a second measurement of the electrical parameter during the charging; and
determining the capacity of the first battery from the first measurement and the second measurement.

2. (canceled)

3. The method of claim 1, wherein the bidirectional charger is one of: (i) a component of an energy management system; and (ii) a component of a first vehicle.

4. The method of claim 1, further comprising setting the first battery to within a high energy region and discharging the first battery from an energy level within the high energy region to within a low energy region by charging to the second battery.

5. The method of claim 4, further comprising determining the energy level of the first battery to be within the high energy region by measuring at least one of: (i) a slope between open circuit voltage and state of charge; (ii) a low hysteresis uncertainty.

6. The method of claim 1, further comprising one of: (i) discharging the first battery to an electrical grid when the second battery is fully charged as a result of discharging the first battery to the second battery; and (ii) charging the first battery from the electrical grid when the second battery is fully discharged as a result of charging the first battery from the second battery.

7. The method of claim 1, wherein the first battery includes a first battery pack and a second battery pack, further comprising performing the active update at the first battery pack and performing the active update at the second battery pack when the active update is completed at the first battery pack.

8. The method of claim 1, wherein running the feasibility check further comprises comparing a first expected total capacity of the first battery to a total initial energy between the first battery and the second battery and comparing a second expected total capacity of the second battery to the total initial energy.

9. The method of claim 8, wherein the feasibility check includes energy consumed by parasitic loads.

10. The method of claim 1, wherein the first battery powers a first vehicle and the second battery is at least one of: (i) a stationary storage system; (ii) a component of a second vehicle; (iii) an electrical grid; and (iv) a peer.

11. An energy management system for performing an active update of a capacity of a first battery, comprising:
a first end point for connecting to the first battery;
a second end point for connecting to a second battery;
a bidirectional charger for connecting the first battery to the second battery;
a controller configured to:
determine a duration of an idle time for the first battery;
determine the first battery is in a charged state;
run a feasibility check of the first battery and the second battery for the active update;
discharge the first battery to the second battery;
obtain a first measurement of an electrical parameter during discharging;
charge the first battery from the second battery;
obtain a second measurement of the electrical parameter during the charging; and
determine the capacity of the first battery from the first measurement and the second measurement.

12. (canceled)

13. The energy management system of claim 11, wherein the bidirectional charger is one of: (i) a component of the energy management system; and (ii) a component of a first vehicle.

14. The energy management system of claim 11, wherein the controller is further configured to set the first battery to within a high energy region and discharge the first battery from an energy level within the high energy region to within a low energy region by charging to the second battery.

15. The energy management system of claim 14, wherein the controller is further configured to determine the energy level of the first battery to be within the high energy region by measuring at least one of: (i) a slope between open circuit voltage and state of charge; and (ii) a low hysteresis uncertainty.

16. The energy management system of claim 11, wherein the controller is further configured to perform one of: (i) discharging the first battery to an electrical grid when the second battery is fully charged as a result of discharging the first battery to the second battery; and (ii) charging the first battery from the electrical grid when the second battery is fully discharged as a result of charging the first battery from the second battery.

17. The energy management system of claim 11, wherein the first battery includes a first battery pack and a second battery pack and the controller is further configured to perform the active update at the first battery pack and perform the active update at the second battery pack when the active update is completed at the first battery pack.

18. The energy management system of claim 11, wherein the controller is further configured to run the feasibility check by comparing a first expected total capacity of the first battery to a total initial energy between the first battery and the second battery and comparing a second expected total capacity of the second battery to the total initial energy.

19. The energy management system of claim 18, wherein the feasibility check includes energy consumed by parasitic loads.

20. The energy management system of claim 11, wherein the first battery powers a first vehicle and the second battery is at least one of: (i) a stationary storage system; (ii) a component of a second vehicle; (iii) an electrical grid; and (iv) a peer.

21. The method of claim 1, further comprising obtaining simultaneous capacity updates of the first battery and the second battery.

22. The energy management system of claim 11, wherein the controller is further configured to obtain simultaneous capacity updates of the first battery and the second battery.
